(19) United States
(12) Patent Application Publication
(10) Pub. No.: US 2021/0126153 A1
(43) Pub. Date: Apr. 29, 2021

(54) BUSBAR-LESS SHINGLED ARRAY SOLAR CELLS AND METHODS OF MANUFACTURING SOLAR MODULES

(71) Applicant: FLEX, Ltd., Singapore (SG)

(72) Inventors: Lisong Zhou, Fremont, CA (US); Huaming Zhou, Wuxi Jiangsu (CN)

(21) Appl. No.: 16/963,180

(22) PCT Filed: Jan. 18, 2018
(86) PCT No.: PCT/CN2018/073255

§ 371 Date: Jul. 17, 2020

(51) Int. Cl. H01L 31/18; H01L 31/05; H01L 31/049; H01L 31/02

(52) U.S. Cl. CPC H01L 31/1876; H01L 31/0201; H01L 31/049; H01L 31/0504

(57) ABSTRACT

A method of forming a solar module. The method includes etching a solar cell, singulating the cell to form strips, and depositing a conductive adhesive on at least one portion of the singulated strips. The strips are then arranged with the conductive adhesive in a shingled manner to form strings of strips such that a portion of each strip overlaps with a portion of the next with the conductive adhesive forming a bond between adjacent strips. A plurality of strings are then connected electrically in parallel to form a set of strings, and a plurality of sets of strings are connected electrically in series. The sets of strings are encapsulated between a front glass and a backsheet and mounted in a frame to form a solar module.

### TECHNICAL FIELD

The present disclosure relates to solar modules, and more particularly, to solar modules forming a shingled array module (“SAM”), which delivers a significantly higher module efficiency than conventional ribbon interconnected modules.

### BACKGROUND

Over the past few years, the use of fossil fuels as an energy source has been trending downward. Many factors have contributed to this trend. For example, it has long been recognized that the use of fossil fuel-based energy options, such as oil, coal, and natural gas, produces gases and pollution that may not be easily removed from the atmosphere. Additionally, as more fossil fuel-based energy is consumed, more pollution is discharged into the atmosphere causing harmful effects on life close by. Despite these effects, fossil-fuel based energy options are still being depleted at a rapid pace and, as a result, the costs of some of these fossil fuel resources, such as oil, have risen. Further, as many of the fossil fuel reserves are located in politically unstable areas, the supply and costs of fossil fuels have been unpredictable.

Due in part to the many challenges presented by these traditional energy sources, the demand for alternative, clean energy sources has increased dramatically. To further encourage solar energy and other clean energy usage, some governments have provided incentives, in the form of monetary rebates or tax relief, for consumers willing to switch from traditional energy sources to clean energy sources. In other instances, consumers have found that the long-term savings benefits of changing to clean energy sources have outweighed the relatively high upfront cost of implementing clean energy sources.

One form of clean energy, solar energy, has risen in popularity over the past few years. Advancements in semiconductor technology have allowed the designs of solar modules and solar panels to be more efficient and capable of greater output. Further, the materials for manufacturing solar modules and solar panels have become relatively inexpensive, which has contributed to the decrease in costs of solar energy. As solar energy has increasingly become an affordable clean energy option for individual consumers, solar module and panel manufacturers have made available products with aesthetic and utilitarian appeal for implementation on residential structures. As a result of these benefits, solar energy has gained widespread global popularity.

### SUMMARY

Further details and aspects of exemplary embodiments of the present disclosure are described in more detail below with reference to the appended figures.

One aspect of the present disclosure is directed to a method of forming a solar module including scribing a solar cell having bus bars on just one side, singulating the solar cell to form strips, each strips having a bus bar on just one side, and depositing a conductive adhesive on a portion of at least some of the singulated strips. The method further includes arranging the strips in a shingled manner to form a string of strips such that at least a bus bar of at least one strip overlaps with a portion of an adjacent strip with the conductive adhesive forming a bond between the bus bar of the strip and a metallization pattern formed on the adjacent strip, connecting the plurality of strings electrically in parallel to form a plurality of sets of strings, connecting the plurality of sets of strings electrically in series, and encapsulating the connected plurality of sets of strings between a frontsheet and a backsheet.

In accordance with a further aspect of the present disclosure the solar cell may include a first metallization pattern on a front side of the solar cell, the first metallization pattern including the at least one bus bar per strip. The first metallization pattern may include fingers, cut lines, or the fingers may extend the entire width across the solar cell.

In accordance with a further aspect of the disclosure, the solar cell may include a second metallization pattern on a back side of the solar cell. The second metallization pattern may include fingers or cut lines or the fingers may extend the entire width across the solar cell. Further the second metallization pattern may be a blank metallization pattern.

In accordance with the present disclosure the solar cell may be a square cell, or a pseudo-square cell. Further, the sets of strings may be supported by an isolation strip, and the electrical connections of the sets of strings may be formed of conductive ribbons supported by the isolation strip.

In accordance with a further aspect of the present disclosure there is described A method of forming a solar module including scribing a solar cell having no bus bars, singulating the solar cell to form strips, depositing a conductive adhesive on a portion of at least some of the singulated strips, and arranging the strips in a shingled manner to form a string of strips such that each strip overlaps with a portion of an adjacent strip with the conductive adhesive forming a bond between the a metallization pattern of a first strip and a metallization pattern of an adjacent strip. The method further includes connecting the plurality of strings electrically in parallel to form a plurality of sets of strings, connecting the plurality of sets of strings electrically in series, and encapsulating the connected plurality of sets of strings between a frontsheet and a backsheet.

In accordance with this aspect of the present disclosure the solar cell may include a first metallization pattern on a front side of the solar cell including fingers. The first metallization pattern may include cut lines, or the fingers may extend the entire width across the solar cell.

The solar cell may include a second metallization pattern on a back side of the solar cell which may include fingers and/or cut lines or the fingers extend the entire width across the solar cell. Further second metallization pattern may be a blank metallization pattern.

### BRIEF DESCRIPTION OF THE DRAWINGS

Various aspects of the present disclosure are described herein below with reference to the drawings, which are incorporated in and constitute a part of this specification, wherein:

FIG. 1 is a perspective view of a known solar cell;

FIG. 2 is a perspective view of a solar cell in accordance with the present disclosure;

FIG. 3 is a front view of a strip of the solar cell of FIG. 2;

FIG. 4 is a back view of the solar cell of FIG. 2 having a first configuration;

FIG. 5 is a back view of the solar cell of FIG. 2 having a second configuration;

FIG. 6 is an illustration of a solar cell representing the front and/or the back of the solar cell;

FIG. 7 is a side view of strips of another solar cell in accordance with the present disclosure, arranged in a shingled pattern;

FIG. 8 is a front view of a string of strips of the solar cell of FIG. 7, formed from pseudo-square solar cells;

FIG. 9 is a front view of a string of strips of the solar cell of FIG. 7, formed from square solar cells;

FIG. 10A is a front view of a solar module in accordance with the present disclosure;

FIG. 10B is a back view of a portion of the solar module of FIG. 10A;

FIG. 11 is a schematic diagram depicting an electrical connection of a solar module in accordance with the present disclosure;

FIG. 12 is a schematic diagram depicting another electrical connection of a solar module in accordance with the present disclosure;

FIG. 13 is a schematic diagram depicting still another electrical connection of a solar module in accordance with the present disclosure;

FIG. 14 is a front view of another solar module in accordance with the present disclosure;

FIG. 15 is a layout diagram depicting the layers of a solar module in accordance with the present disclosure;

FIG. 16 is a top view of a bussing ribbon example in accordance with the present disclosure; and

FIG. 17 is a flow chart describing a method of forming a solar module in accordance with the present disclosure.

FIG. 18 is a perspective view of a solar cell in accordance with the present disclosure;

FIG. 19 is a front view of a string of strips of the solar cell of FIG. 18 in accordance with the present disclosure;

FIG. 20 is a front view of a string of strips, of which one side has a bus bar, of the solar cell of FIG. 18 in accordance with the present disclosure; and

FIG. 21 is a side view of strips of the solar cell of FIG. 18 in accordance with the present disclosure arranged in a shingled pattern.

### DETAILED DESCRIPTION

The present disclosure is directed to a solar cell formed without bus bars and solar modules formed of solar cells or portions of solar cells formed without bus bars. Further, the present disclosure is directed to solar cells and solar modules requiring reduced amounts of silver or other conductive materials.

The solar cells of the present disclosure are used as the building block of solar modules. The solar cell is made up of a substrate configured to be capable of producing energy by converting light energy into electricity. Examples of suitable photovoltaic substrate material include, but are not limited to, those made from multicrystalline or monocrystalline silicon wafers. These wafers may be processed through the major solar cell processing steps, which include wet or dry texturization, junction diffusion, silicate glass layer removal and edge isolation, silicon nitride anti-reflection layer coating, front and back metallization including screen printing, and firing. The wafers may be further processed through advanced solar processing steps, including adding rear passivation coating and selective patterning to thereby obtain a passivated emitter rear contact (PERC) solar cell, which has a higher efficiency than solar cells formed using the standard process flow mentioned above. The solar cell may be a p-type monocrystalline cell or an n-type monocrystalline cell. Similar to the diffused junction solar cells described as above, other high efficiency solar cells, including heterojunction solar cells, can utilize the same metallization patterns in order to be used for the manufacture of a shingled array module. The solar cell may have a substantially square shape with chamfered corners (a pseudo-square) or a full square shape.

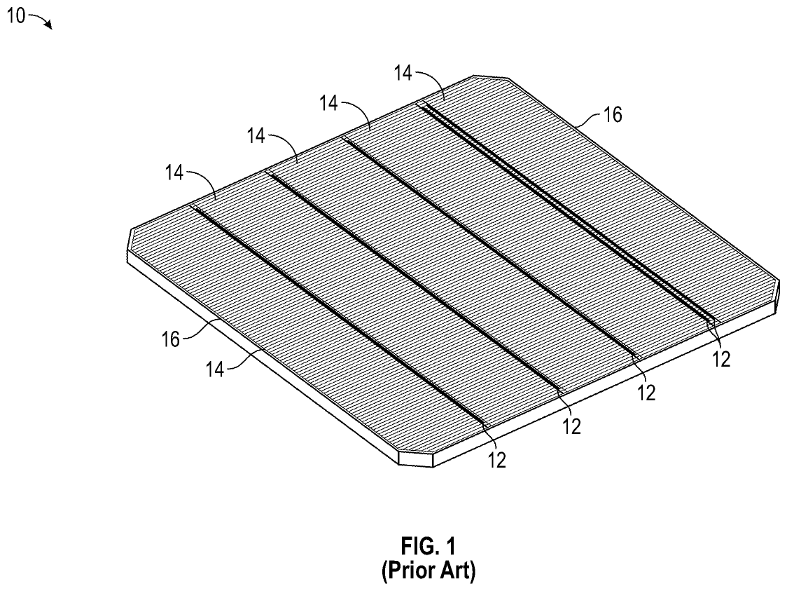

FIG. 1 depicts a known solar cell 10, from a front side thereof. The solar cell 10 includes five (5) bus bars 12. Finger lines 14 extend across each of the portions of the solar cell 10 and terminate the ends thereof at the edges 16 of the solar cell 10 and/or the bus bars 12. The finger lines 14 and bus bars 12 together form a metallization pattern of the solar cell 10. Typically the metallization pattern is formed of a conductor such as silver and is printed on the solar cell 10 during manufacturing. As can be appreciated, reduction of the amount of silver in the metallization pattern can result in significant cost savings.

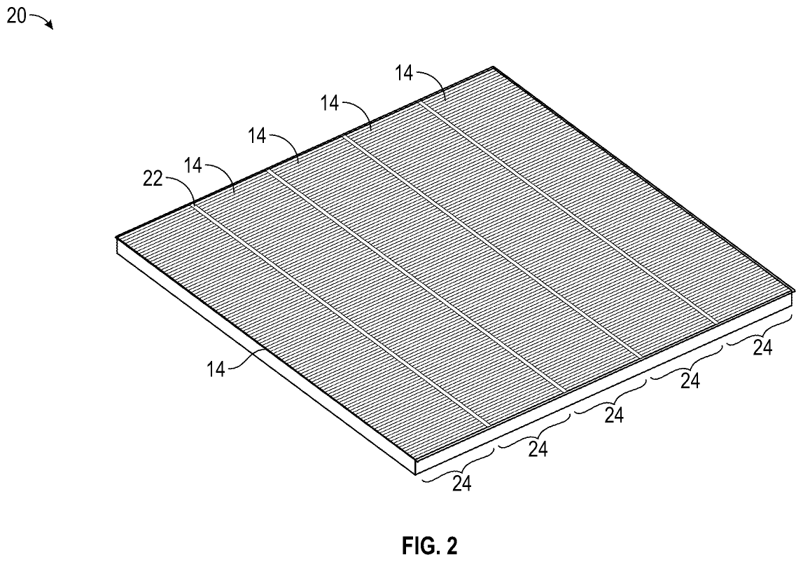

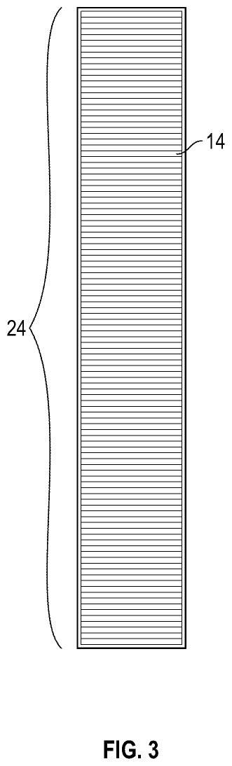

FIG. 2 depicts a front side configuration of a solar cell 20 in accordance with the present disclosure. The solar cell 20 includes finger lines 14, but no bus bars are formed on the solar cell. Rather, cut lines 22 separate the finger lines 14 from extending across the entirety of the solar cell 20. These cut lines 22 are the lines along which the solar cell 20 will be etched or scribed (described in greater detail below) and then separated into individual strips 24. In contrast with the known solar cell 10 of FIG. 1, the solar cell 20 in FIG. 2 has a square design, whereas that of FIG. 1 has a pseudo-square design. As noted above, those of skill in the art will recognize that the embodiment of FIG. 2 may also be formed in a pseudo-square without departing from the scope of the present disclosure. FIG. 3 depicts a single strip 24.

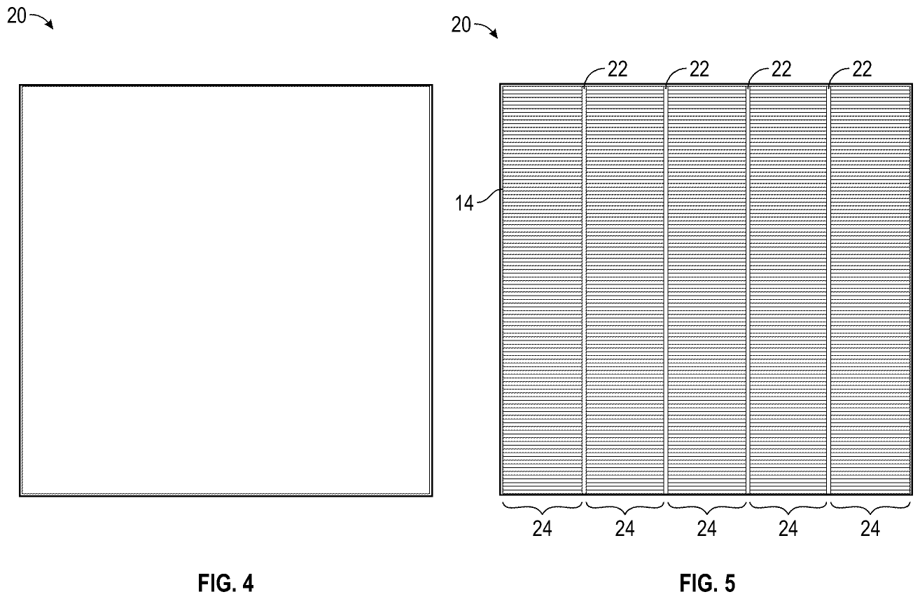

FIGS. 4 and 5 depict two different variations of a back side configuration of the solar cell 20 depicted in FIG. 2. In FIG. 4, there are no finger lines, thus a solar cell 20 having this configuration has limited, if any, ability to collect solar energy via the backside of the solar cell. However, as will be appreciated, in view of the lack of bus bars 12, no silver or other conductive material is used in forming the bus bars on the back side of such a solar cell. In contrast to FIG. 4, the embodiment of FIG. 5 shows a solar cell 20 having a surface with fingers 14 formed between cut lines 22, to define individual strips 24. FIG. 5 is in fact nearly identical to FIG. 2 such that the front and back sides of the solar cell 20 so manufactured are nearly identical. Alternatively, the fingers 14 formed on the back side may have a greater density, that is there are more of them than on the front side. An example of this can be seen in U.S. Design patent application Ser. No. 29/624,485 filed Nov. 1, 2017 entitled SOLAR CELL the entire contents of which are incorporated herein by reference.

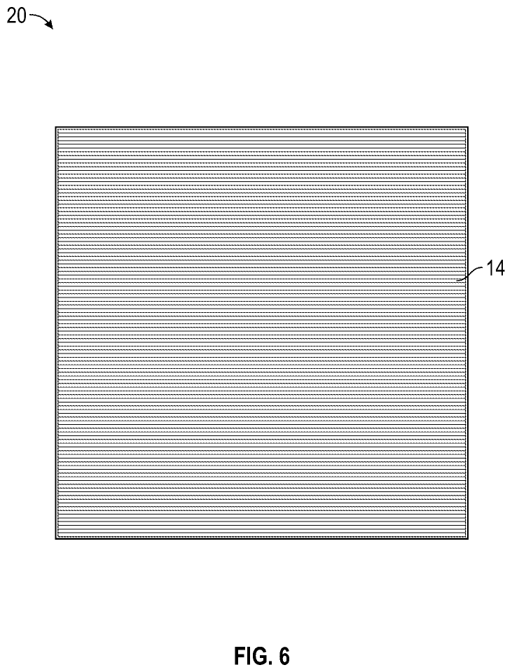

In a further embodiment, as depicted in FIG. 6, either or both of the front surface or the back surface of solar cell 20 can be formed without cut lines 22, and instead the fingers 14 extend the entire width across the solar cell.

Once the solar cells 20 are manufactured with the finger 14 patterns either with or without the cut lines 22 as depicted at least in FIG. 2, the cells are ready to be singulated. Singulation is the breaking or separation process after etching along the cut line 22. The etching removes material, for example, in the cut line 22, to weaken the solar cell 20. Each etching has a depth of between about 10% and about 90% of wafer thickness. The etching may be formed using a laser, a dicing saw, or the like. In an embodiment, the etching extends across the solar cell 20 from edge to edge. In another embodiment, the scribe lines, formed by the etching, extend from one edge to just short of an opposite edge of the solar cell 20. Once weakened, application of a force to the weakened areas results in the breaking of the solar cell 20 along the etching to form strips 24 as depicted in FIG. 3. In the example of the solar cell 20, five individual strips 24 are formed. As will be appreciated, any suitable number of strips, e.g., 3, 4, 5, or 6 strips, can be formed during singulation depending upon the original construction of the solar cell 20.

In order to singulate, the solar cell 20 is placed on a vacuum chuck including a plurality of fixtures which are aligned adjacent each other to form a base. The vacuum chuck is selected so that the number of fixtures matches the number of discrete sections of the solar cell 20 to be singulated into strips 24. Each fixture has apertures or slits, which provide openings communicating with a vacuum. The vacuum, when desired, may be applied to provide suction for mechanically temporarily coupling the solar cell 20 to the top of the base. To singulate the solar cell 20, the solar cell 20 is placed on the base such that the each discrete section is positioned on top of a corresponding one of the fixtures. The vacuum is powered on and suction is provided to maintain the solar cell 20 in position on the base. Next, the fixtures are moved relative to each other. In an embodiment, multiple ones of the fixtures move a certain distance away from neighboring fixtures thereby causing the discrete sections of the solar cell 20 to likewise move from each other and form resulting strips 24. In another embodiment, multiple ones of the fixtures are rotated or twisted about their longitudinal axes thereby causing the discrete sections of the solar cell 20 to likewise move and form resulting strips 24. The rotation or twisting of the fixtures may be effected in a predetermined sequence, in an embodiment, so that no strip 24 is twisted in two directions at once. In still another embodiment, mechanical pressure is applied to the back surface of the solar cell 20 to substantially simultaneously break the solar cell 20 into the strips 24. It will be appreciated that in other embodiments, other processes by which the solar cell 20 is singulated may alternatively be implemented.

After the solar cell 20 is singulated, the strips 24 are sorted. As will be appreciated the two end strips 24 of a pseudo-square solar cell 20 (see, e.g., FIG. 1) will have a different shape (chamfered corners) than the center three strips 24 (rectangular) or all the strips of a square solar cell 20 (FIG. 2). Like formed strips 24 are collected and sorted together. In an embodiment, sorting strips 24 is achieved using an auto-optical sorting process. In another embodiment, the strips 24 are sorted according to their position relative to the full solar cell 20. After sorting, strips 24 having chamfered corners are segregated from those strips 24 having rectangular non-chamfered corners. For further processing, in accordance with the present disclosure, only like strips 24 are used together (either chamfered or rectangular). Further, depending on which configuration of front and back surfaces (FIGS. 2-6, etc.) the segregation may require ensuring that the strips 24 are properly aligned with one another.

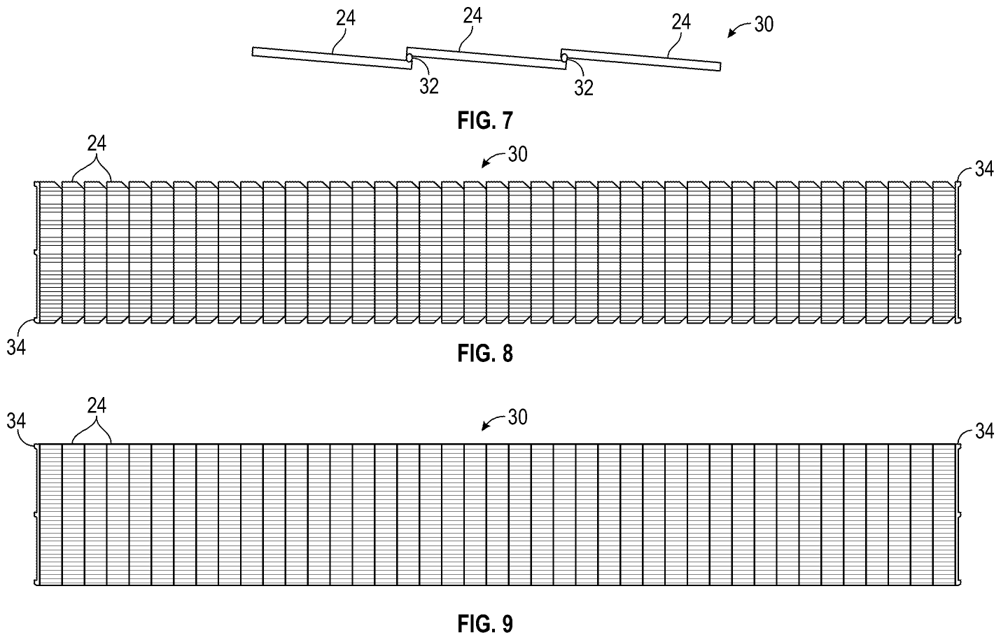

Once sorted and segregated, the strips 24 are ready to be assembled into strings 30. To form strings 30, as shown in FIG. 7, multiple strips 24 are aligned in an overlapping orientation. An electrically-conductive adhesive 32 is applied to a front surface of a strip 24 along an edge of the strip 24 and an edge along a bottom surface of a neighboring strip is placed into contact with the electrically-conductive adhesive 32 to mechanically and electrically connect the two strips 24. As will be appreciated, the electrically-conductive adhesive 32 may be applied to a back surface of a strip 24 and then placed in contact with the front surface of a neighboring strip 24. The electrically-conductive adhesive 32 may be applied as a single continuous line, as a plurality of dots, dash lines, for example, by using a deposition-type machine configured to dispense adhesive material to a bus bar surface. In an embodiment, the adhesive 32 is deposited such that it is shorter than the length of the strip 24 and has a width and thickness to render sufficient adhesion and conductivity. The steps of applying the adhesive 32 and aligning and overlapping the strips 24 are repeated until a desired number of strips 24 are adhered to form the string 30. A string may include, for example, 10 to 100 strips.

FIG. 8 depicts a top view of a string 30 formed of multiple strips 24, by the process outlined above with respect to FIG. 7. In FIG. 8, the chamfered corner strips 24 are adhered together. The end of the string 30 includes a metal foil 34 soldered or electrically connected using electrically-conductive adhesive 32 to the end strip 24. The metal foil 34 will be further connected to a module interconnect bus bar so that two or more strings together form the circuit of a solar module, as will be discussed in detail below. In another embodiment, the module interconnect bus bar can be directly soldered or electrically connected to the end strip 24 to form the circuit. In another embodiment as illustrated in FIG. 9, rectangular strips 24 are adhered to each other to form a string 30. Similar to the string 30 shown in FIG. 8, the string 30 includes, for example, 10 to 100 strips 24 with each strip 24 overlapping an adjacent strip 24. The string 30 of FIG. 9 also includes electrical connections for coupling to another similarly configured string 30.

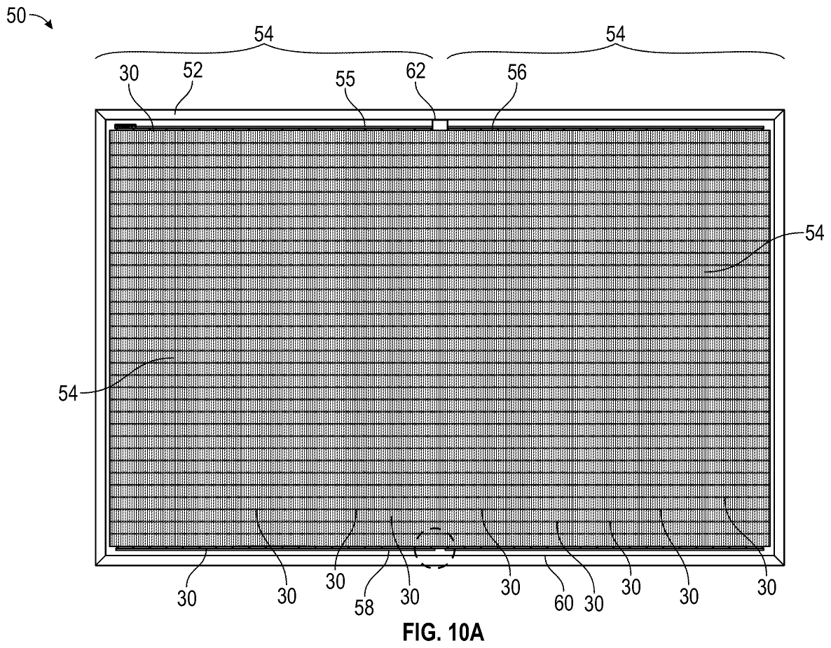

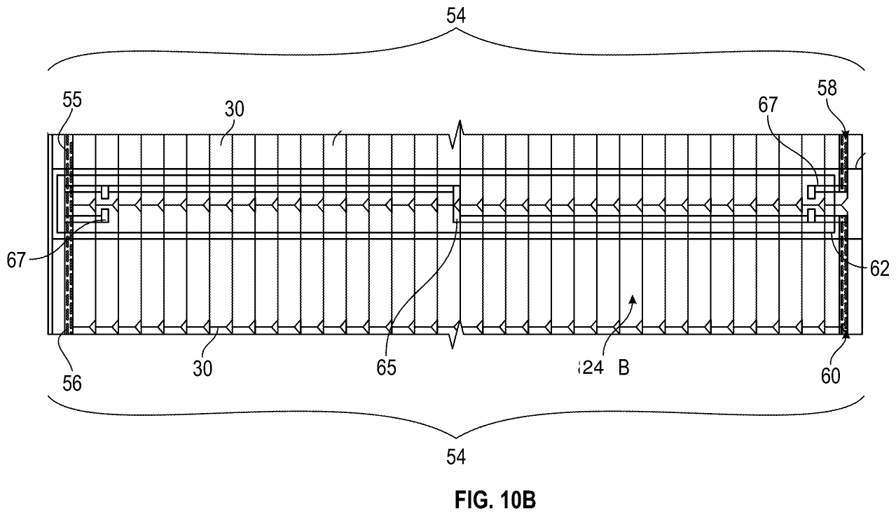

FIG. 10 is a front view of a solar module 50 in accordance with an embodiment of the present disclosure. The solar module 50 includes a back sheet (described in greater detail below) and a frame 52 surrounding all four edges of the solar module 50. The frame 52 is formed from anodized aluminum or another lightweight rigid material.

Strings 30 formed of strips 24, ten of which are shown here, are disposed over the back sheet. Although not specifically depicted, it will be appreciated that a front sheet layer (e.g. glass, a transparent polymer, etc.) is disposed over the strips 24 and electrical connections associated therewith for protective purposes. Here, the strips 24 are rectangular. The strings 30 are disposed side-by-side lengthwise across the solar module 50.

The edges of any two adjacent strings 30 are spaced apart providing a small gap 54 there between. The gap 54 has a substantially uniform width (taking into account manufacturing, material, and environmental tolerances) between the two adjacent strings 30 of about 1 mm to about 5 mm. In another embodiment, the edges of two or more of the strings 30 are immediately adjacent each other.

The strings 30 are grouped together, for example, in FIG. 10A as a set 54 of five (5) strings 30. These five (5) strings are arranged electrically in parallel. A second set 54 of five (5) strings 30, also connected electrically in parallel, are grouped together and form the second half of the solar module 50. At a top edge of the solar module 50, one set 54 of strings 30 is connected to a bus bar 55 which extends along a portion of width of the solar module 50 and the second set 54 of strings 30 is connected to a second bus bar 56. At a bottom edge of the solar module 50 two bus bars 58 and 60 complete the electrical connections of the sets 54 of strings 30. As a result, as shown in FIG. 10A, the strings 30 of each set 54 are connected in parallel with each other and each set 54 is then connected in series with the other. An isolation strip 62 (which may ultimately be hidden from view) is disposed between the two string sets 54 to provide support. The isolation strip 62 is greater in length than the strings 30 and is sufficiently wide to permit the adjacent strings 30 of the two string sets 54, respectively, to overlap a portion of the isolation strip 62.

In accordance with one embodiment, the series connection of the first string set 54 to the second string set 54 can be made by attaching the negative side of the first string set 54 and the positive side of the second string set 54 to a common bus bar. Alternatively, positive sides of both the first and second string sets 54 may be placed on the same side of the solar module and a cable, wire, or other connector may be used to electrically connect the negative side of the first string set 54 to the positive side of the second string set 54. This second configuration promotes efficiency in manufacturing by allowing all string sets 54 to be placed in the solar module without reorientation of one of them, and reduces the size of the bus bars, as well as making all bus bars of similar length rather than having one side be long and the other side formed of two short bus bars, thus reducing the number of components of the entire module 50.

FIG. 10B depicts a portion of a back side of the solar module 50 with the back sheet removed, illustrating an isolation strip 62 and associated electrical connections configured to be disposed between the two string sets 54 to electrically connect and structurally support the string sets 54. As will be appreciated, the isolation strip 62 and associated electrical connections are disposed underneath adjacent strings 54. In an embodiment, the isolation strip 62 is a cut portion of the back sheet material and is held in place by an adhesive layer 63. The adhesive layer 63 may be formed from ethylene vinyl acetate (EVA) or another hot melt type of encapsulation materials. The isolation strip 62 may be greater in length than the strings 54. In another embodiment, the isolation strip 62 is sufficiently wide to permit the adjacent strings 30 of the two string sets 54, to overlap a portion of the isolation strip 62. As detailed in FIG. 10B, the isolation strip 62 is rectangular. One end of the isolation strip 62 extends past the ends of the strings 30, in an embodiment so that a portion of each of two of the top bus bars 55, 56 is disposed across a portion of its width.

As depicted in FIG. 10B, an electrically conductive ribbon 65 extends substantially perpendicularly from top bus bar 55 behind string 30 and about half down the length of the isolation strip 62 and makes a turn to extend behind the other string 30 to connect to bottom bus bar 60. In this way, a string 30 (or a set 54) having a first polarity may be connected directly to a string 30 (or set 54) having an opposite polarity. Two additional electrically conductive ribbons 67 are included to provide connection to junction boxes (now shown)), each serving as terminals having opposite polarity. In this regard, one ribbon 67 extends from top bus bar 56 and a second ribbon 67 extends from bottom bus bar 58 so that each conductive ribbon serves to connect the strings 30 to junction boxes of different polarity. Fix tape (not shown) is included to maintain the conductive ribbons 65, 67 in position on the isolation strip 62 relative to the strings 30. This arrangement is but one electrical connection arrangement enabling electrical connection of two sets 54 of strings 30 in series in a solar module 50. Other electrical connections and arrangements can be made without departing from the scope of the present disclosure.

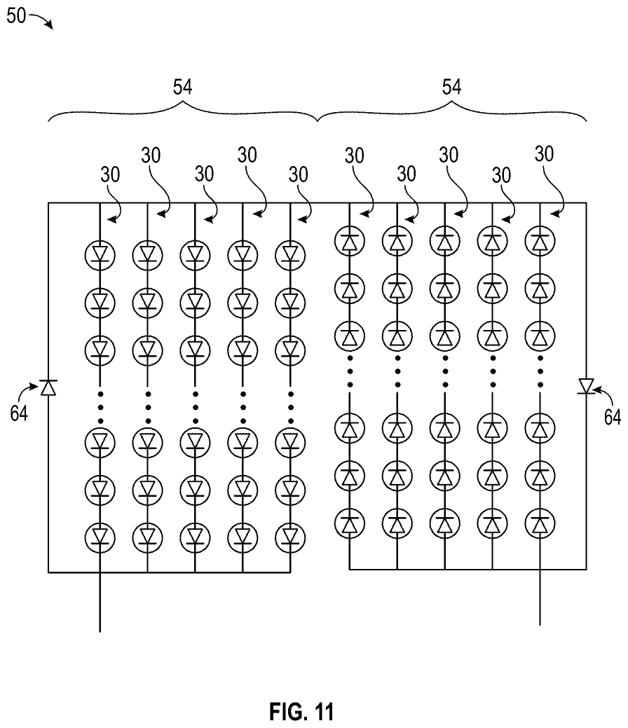

As alluded to above, the solar module 50 may incorporate any one of numerous electrical configurations. For example, turning to FIG. 11, an electrical schematic for solar module 50 is provided, where ten strings 30 are grouped into two sets 54 of strings 30. The strings of the first set of strings 54 are connected in parallel with each other and include a bypass diode 64. Similarly, the strings of the second set 54 of strings 30 are connected in parallel with each other and include a bypass diode 64. The two sets of strings 54 are connected in series with each other.

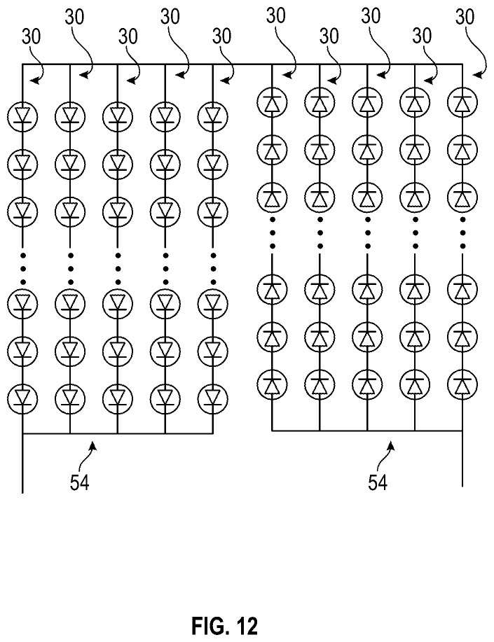

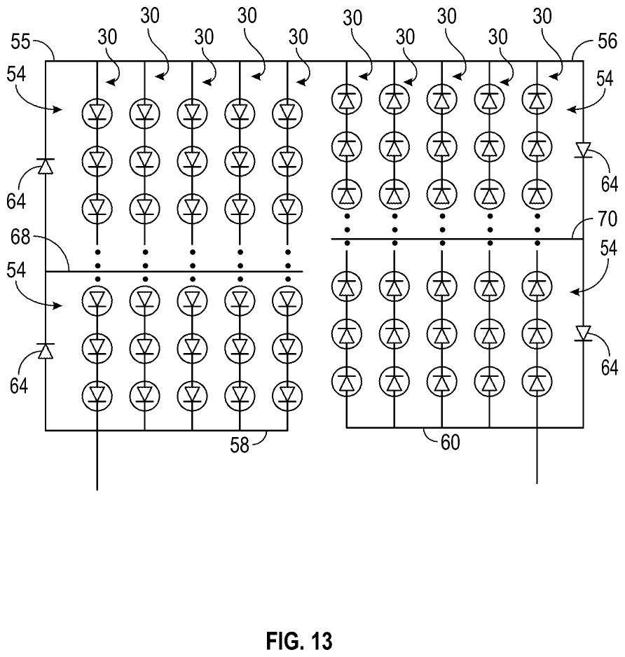

In another embodiment as illustrated in FIG. 12, an electrical schematic for solar module 50 is provided that is identical to the electrical schematic provided in FIG. 11, except no bypass diodes are included. FIG. 13 is another embodiment of an electrical schematic for solar module 50. Here, the strings 30 are grouped into four sets of strings 54 which span just half the distance between the bus bars 55 and 58 and bus bars 56 and 60. In one embodiment, intermediate bus bars 68 and 70 connect two sets 54 of strings 30 in parallel. The result is four (4) sets 54 of strings 30 which are arranged in series. Within each set 54, the strings 30 are arranged in parallel as described above. As depicted in FIG. 13, each set 54 includes a bi-pass diode 64.

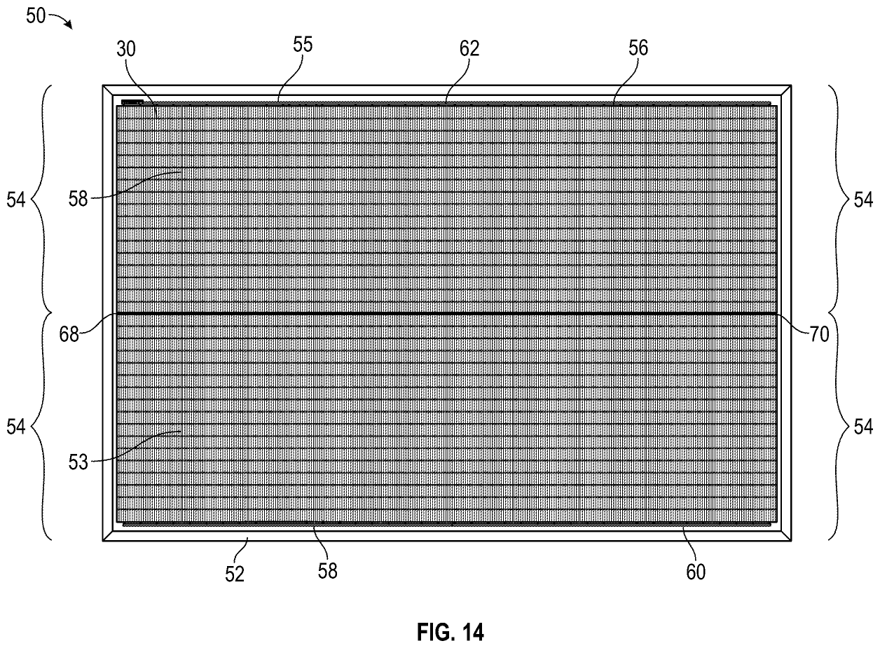

FIG. 14 is a front side view of a solar module 50 formed in accordance with the electrical schematic of FIG. 13. As can be seen there are four sets 54 of strings 30, each set 54 is connected to a bus bar 55, 56, 58, 60 connected to the frame 52, and intermediate bus bars 68 and 70.

As will be appreciated, the sets 54 may be directly connected via the bus bars 55, 56, 58, 60, 68, and 70, or may be electrically connected via junction boxes located on a backside of the solar module 50. The junction box(s) may also contain the bypass diodes 64, when employed.

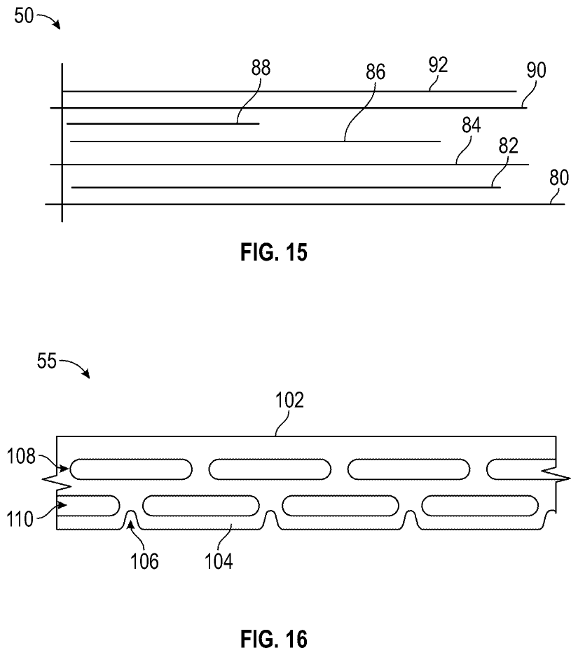

FIG. 15 is a simplified cross-sectional view of a solar module 50 after construction. As shown, solar module 50 has a front sheet layer 80, which serves as a front of the solar module 50, an EVA layer 82, a ribbon layer 84, a set of strings layer 86, e.g., set 54 of strings 30 (FIG. 10A), an isolation strip layer 88, a rear EVA layer 90, and a back sheet layer 92. Though layers 80 and 92 are described in some instances as being formed of glass, they may also be formed of transparent polymers and other materials other than glass without departing from the scope of the present disclosure.

FIG. 16 is a top view of a bussing ribbon configuration of a bus bar 55, in accordance with an embodiment. All bus bars 55, 56, 58 60, 68 and 70 referenced herein may have the same or similar construction. The bus bar 55 is in the form of a thin metallized tape having a solid edge 102, which in use may be disposed substantially parallel with a long edge of the solar module 50. The bus bar 55 also has a notched edge 104 that is disposed closest to the strings 30. Notches 106 formed along the notched edge 104 are substantially equally spaced along the length of the bus bar 55. Notches 106 are configured so that when the strings 30 are soldered to the ribbon bus bar 55, soldering stresses are reduced. Otherwise, high soldering stresses could cause unwanted microcracks in one or more of the strips 30, which could affect product yield and reliability. In another embodiment, the notches 106 are unequally spaced. Openings formed in two substantially parallel rows 108, 110 are defined in the ribbon bus bar 55, which promotes flexibility of the bus bar 55.

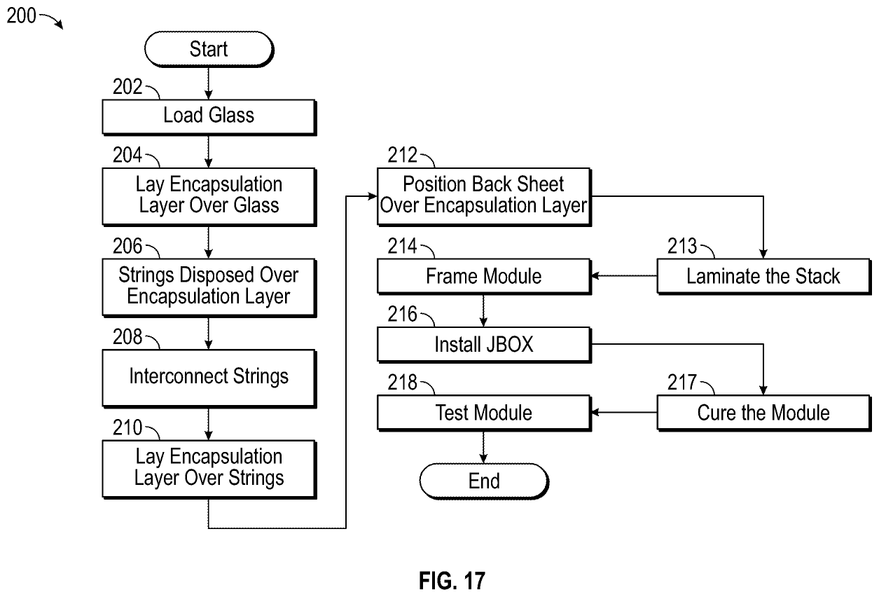

FIG. 17 is a flow diagram of a method 200 of manufacturing a solar module, such as the solar module 50 described above, or other suitable solar module. Referring to FIG. 17, in connection with FIGS. 10A and 10B, in an embodiment, a front sheet (e.g., a glass plate is loaded as the substrate at step 202, then an encapsulation layer, such as ethylene vinyl acetate (EVA) or poly olefin (POE) film, is laid on top of front sheet at step 204. Next, string sets 54 are disposed over the encapsulation layer at step 206. In an embodiment, a desired number of string sets 54 can be appropriately positioned and electrically connected by module interconnect bus bars, e.g., bus bars 55, 56, 58, 60, 68, 70, to form a desired circuit configuration. For example, the solar module 50 to be manufactured may be made up of ten (10) sets of strings 30 and hence, may have a length of between about 1600 mm to about 1700 mm, a width of between about 980 mm to about 1100 mm, and a thickness of between about 2 mm to about 60 mm. In another embodiment, the solar module 50 may be made up of one (1) to eighteen (18) sets 54 of strings 30 and the front sheet can have a length of between about 500 mm to about 2500 mm, a width of between about 900 mm to about 1200 mm, and a thickness of between about 2 mm to about 60 mm.

The string 30 sets 54 are positioned over an EVA layer and front sheet in a configuration as described above with respect to the solar module 50. The string 30 sets 54 may be placed one at a time over the EVA layer, in an embodiment. Alternatively, the desired number of string 30 sets 54 may be substantially simultaneously placed over the EVA layer, or multiple at a time. Suitable machinery for automated laying up of the string 30 sets 54 commonly used in mass production of solar modules 50 may be employed.

To form connections between the string 30 sets 54, the strings 30 are interconnected at step 208. For example, bus bars, e.g., bus bars 55, 56, 58, 60, 68, 70, are electrically connected to corresponding portions of the string 30 sets 54 via conductive ribbon material. An isolation strip 62 including suitably positioned electrically conductive ribbon 65, 67 adhered thereto, is positioned to extend between two adjacent string 30 sets 54 in a manner as described above. Electrical wires to be hidden in a junction box (not shown) are either protected or otherwise isolated in order to permit the wires to be placed in the junction box at later stages of manufacture.

Next, another encapsulation layer is laid on top of the string sets at step 210. Then, a back sheet is positioned over the encapsulation layer at step 212 to form one or more lamination stacks. The back sheet material protects the solar module circuitry from environmental impact. In an embodiment, the back sheet is dimensioned slightly larger than the glass plate to improve the manufacturing yield. In another embodiment, the back sheet material can be replaced with glass to offer even better protection from environment.

After the back sheet layup, the lamination stacks are loaded into a vacuum lamination chamber in which the stacks are adhered to each other under a high temperature profile in vacuum, at step 213. The particular details of the lamination process are dependent on the specific properties of the encapsulation material used.

After lamination, the module is framed at step 214. Framing is employed to provide mechanical strength that is sufficient to withstand wind and snow conditions after the solar module is installed. In an embodiment, the framing is made up of anodized aluminum material. In another embodiment, the framing is disposed on an outer edge of the module. In still another embodiment, the framing extends over a portion of the front sheet and/or the back sheet. Additionally, silicone is used to seal the gap between glass and framing so that the edges of the solar module are protected from unwanted materials that may unintentionally become trapped within the module which can interfere with the operation of the solar module. As will be appreciated embodiments without framing are also contemplated within the scope of the present disclosure.

After framing, a junction box is installed on the back sheet, and the interconnect ribbon 65, 67 and bus bars, e.g., bus bars 55, 56, 58, 60, 68, 70, are soldered or clamped to contact pads in the junction box at step 216. Silicone potting material may be used to seal the edge of junction box to prevent moisture and or contaminants getting into the module. In addition, the junction box itself may be potted to prevent the component from corrosion. In embodiments, the module is cured at step 217.

The module is tested at step 218. Examples of tests include, but are not limited to flash testing to measure the module power output, electroluminescence testing for crack and micro-crack detection, grounding testing and high pot testing for safety, and the like.

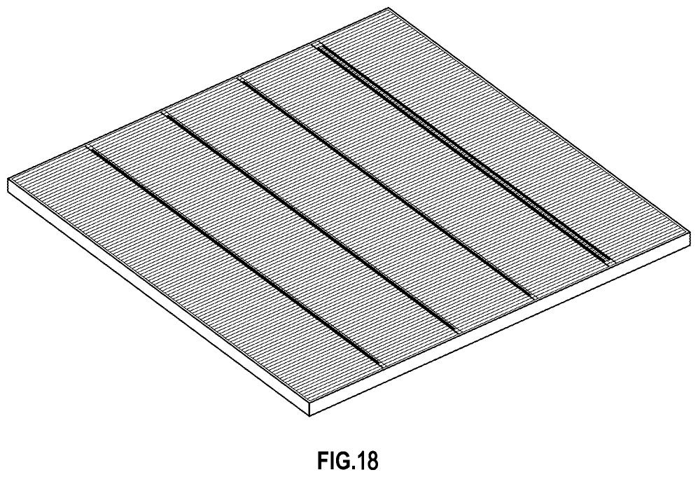

Though the embodiments herein are typically described herein as being bus bar-less, a hybrid approach is also contemplated within the scope of the present disclosure. FIG. 18 depicts a perspective view of a solar cell 10 in accordance with the present disclosure. The solar cell 10. The solar cell 10 is similar in construction that that depicted in FIG. 1, and indeed, the pseudo-square cell of FIG. 1 could also be utilized without departing from the scope of the present disclosure. In the embodiment of FIG. 1, bus bars 12 and fingers lines 14 are formed on the top surface of the solar cell 10. As will be appreciated, the “top surface” or front side of the solar cell 10 could also be formed as the bottom surface of back side of the solar cell.

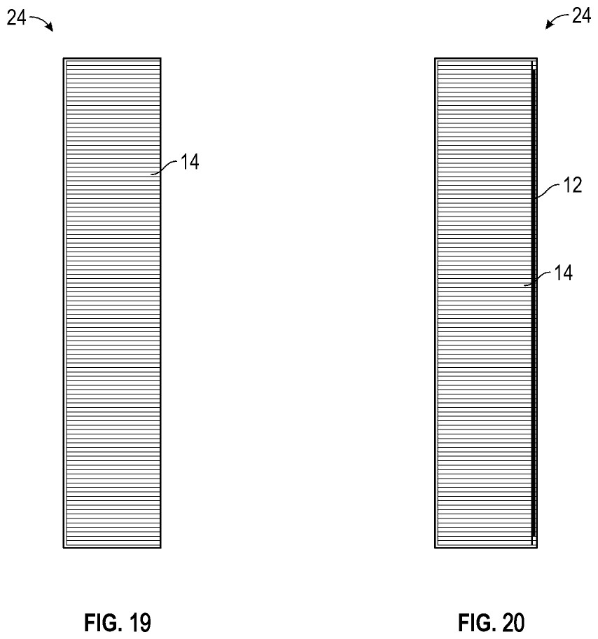

In contrast with the prior cells described herein that are formed without bus bars 12, the instant embodiment has bus bars 12 formed on one side of the solar cell 10. On the side opposite that having bus bars 12, the solar cell 10 may be formed similar to the surfaces depicted in any of FIGS. 4-6. A cell formed having a top surface as depicted in FIG. 18 and a back surface formed as depicted in either FIG. 5 or 6, upon singulation will result in strips as depicted in FIGS. 19 and 20 for the combination of FIG. 18 and FIG. 6, FIGS. 3 and 20 for the combination of FIG. 18 and FIG. 5. As can be seen by comparing FIG. 3 or 19 with FIG. 20 20, only one side of the strip has a bus bar 12.

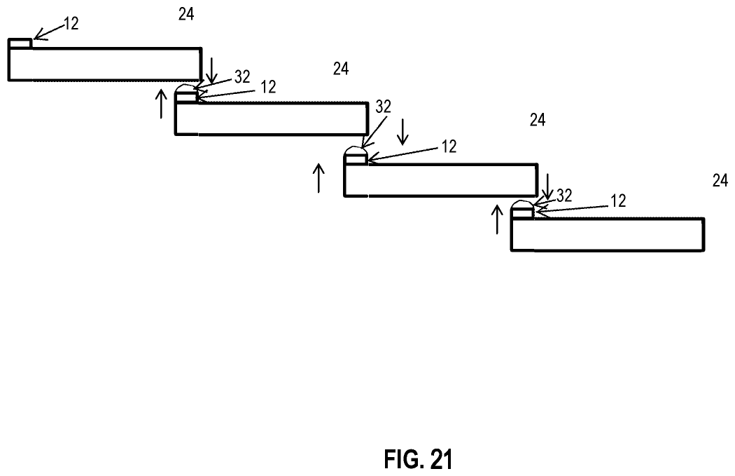

Following singulation, as described above, the strips 24 are assembled in a shingled pattern as depicted in FIG. 21. As can be seen, the bus bar 12, in this instance formed on a top side of the strip 24, is adhered to the bottom surface of another strip 24 using ECA 32, as described elsewhere above. The ECA creates an electrical connection between the bus bar 12 formed on a top surface of one strip 24 and the finger lines 14 formed on a bottom surface of a neighboring strip 24. Again, by having bus bars 12 formed on just one side of the strip 24, the overall amount of silver or other conductor deposited on the solar cell 10 can be reduced. However, by having bus bars 12 formed on at least one of the surfaces, sufficient conductivity and continuity can be established between the bus bar 12 and the finger liens 14 of the neighboring strip 24 to minimize resistance and limit thermal losses at the junction of the two strips. Note that while shown with the bus bars 12 formed on a top surface of the strips 24, the bus bars 12 could alternatively be formed on a bottom surface of the strip 24 and connect to finger lines 14 formed on the top surface of the strip, without departing from the scope of the present disclosure. The other aspects of formation of a solar module, singulation, and electrical connection of the strips 24 into strings 30 are essentially unchanged for an embodiment having no bus bars 12 and an embodiment having bus bars 12 formed only on one side of the solar cell 10 or strip 24.

While described herein as occurring on a particular side of the solar cell. The described cut lines, fingers, metalization patterns, bus bars, etc., may appear in any combination on either side of the solar cell without departing from the scope of the present disclosure. Further after forming into strips, the individual strips will either have a bus bar on one side, or no bus bars on either side.

While several embodiments of the disclosure have been shown in the drawings, it is not intended that the disclosure be limited thereto, as it is intended that the disclosure be as broad in scope as the art will allow and that the specification be read likewise. Any combination of the above embodiments is also envisioned and is within the scope of the appended claims. Therefore, the above description should not be construed as limiting, but merely as exemplifications of particular embodiments. Those skilled in the art will envision other modifications within the scope of the claims appended hereto.

1. A method of forming a solar module comprising:
scribing a solar cell having a front side metallization pattern including bus bars;
singulating the solar cell to form strips, each strips having a bus bar on just one side;
depositing a conductive adhesive on a portion of at least some of the singulated strips;
arranging the strips in a shingled manner to form a string of strips such that at least a bus bar of at least one strip overlaps with a portion of an adjacent strip with the conductive adhesive forming a bond between the bus bar of the strip and a back side metallization pattern formed on the adjacent strip, wherein the back side metallization pattern is without fingerlines and bus bars, or is comprised of just fingerlines;
connecting the plurality of strings electrically in parallel to form a plurality of sets of strings;
connecting the plurality of sets of strings electrically in series; and
encapsulating the connected plurality of sets of strings between a frontsheet and a backsheet.

2. The method of claim 1 wherein the first metallization pattern on a front side of the solar cell, the first metallization pattern including the at least one bus bar per strip.

3. The method of claim 2, wherein the first metallization pattern includes fingers.

4. The method of claim 3, wherein the first metallization pattern includes cut lines.

5. The method of claim 3, wherein the fingers extend the entire width across the solar cell.

6. (canceled)

7. (canceled)

8. The method of claim 1, wherein the second metallization pattern includes cut lines.

9. The method of claim 1, wherein the finger lines extend the entire width across the solar cell.

10. (canceled)

11. The method of claim 1, wherein the solar cell is a square cell.

12. The method of claim 1, wherein the solar cell is a pseudo-square cell.

13. The method of claim 1, wherein the sets of strings are supported by an isolation strip.

14. The method of claim 13, wherein the electrical connections of the sets of strings are formed of conductive ribbons supported by the isolation strip.

15. A method of forming a solar module comprising:
scribing a solar cell including at least a first metallization pattern, wherein the first metallization pattern includes only finger lines;
singulating the solar cell to form strips;
depositing a conductive adhesive on a portion of at least some of the singulated strips;
arranging the strips in a shingled manner to form a string of strips such that each strip overlaps with a portion of an adjacent strip with the conductive adhesive forming a bond between the a metallization pattern of a first strip and a metallization pattern of an adjacent strip;
connecting the plurality of strings electrically in parallel to form a plurality of sets of strings;
connecting the plurality of sets of strings electrically in series; and
encapsulating the connected plurality of sets of strings between a frontsheet and a backsheet.

16. (canceled)

17. The method of claim 15, wherein the first metallization pattern includes cut lines.

18. The method of claim 15, wherein the finger lines extend the entire width across the solar cell.

19. The method of claim 15 wherein the solar cell includes a second metallization pattern on a back side of the solar cell.

20. The method of claim 19, wherein the second metallization pattern includes fingers.

21. The method of claim 19, wherein the second metallization pattern includes cut lines.

22. The method of claim 20, wherein the fingers extend the entire width across the solar cell.

23. The method of claim 19, wherein the second metallization pattern is a blank metallization pattern.
